(19) United States
(12) Patent Application Publication
(10) Pub. No.: US 2025/0384180 A1
(43) Pub. Date: Dec. 18, 2025

(54) A SYSTEM DEVELOPED FOR CONTROLLING THE DATA FLOW OF THE DIGITAL TWIN-BASED INTELLIGENT TRANSPORTATION APPLICATIONS AND MODELING OF THE DATA AND AN OPERATION METHOD THEREOF

(71) Applicant: BTS KURUMSAL BILISIM TEKNOLOJILERI ANONIM SIRKETI, Atasehir/Istanbul (TR)

(72) Inventors: Kübra DURAN, Sariyer/Istanbul (TR); Lal Verda ÇAKIR, Atasehir/Istanbul (TR); Berk CANBERK, Sariyer/Istanbul (TR); Gökhan YURDAKUL, Üsküdar/Istanbul (TR); Özgür PALANTÖKEN, Pendik/Istanbul (TR)

(21) Appl. No.: 19/116,336

(22) PCT Filed: Dec. 29, 2023
(86) PCT No.: PCT/TR2023/051855

§ 371 Date: Mar. 27, 2025

(30) Foreign Application Priority Data
Dec. 20, 2023 (TR) 2023/017763

(51) Int. Cl. G06F 30/18

(52) U.S. Cl. CPC G06F 30/18

(57) ABSTRACT

The invention relates to a system developed for controlling the two-way real-time data flow and modeling the data in the digital twin-based (DT) intelligent transportation applications and an operation method of this system.

### TECHNICAL FIELD

The invention relates to a system developed for controlling the two-way real-time data flow and modeling the data in the digital twin-based (DT) intelligent transportation applications and an operation method of this system.

### STATE OF THE ART

A digital twin is defined as a real-time virtual model of an object or a system. A digital twin uses the real data about a real-life object or a system as input and generates control strategies and predictions about how the real object or system will react.

A digital twin is generally programmed and developed by data science experts or experts in the field in which the digital twin will be implemented. First, the structure of the real object or system that is being twinned is investigated, and afterwards this data is used to develop a data-driven model that simulates the original one in the real world. Such a process is called digital twin modeling.

The digital twins are used to virtually design and test objects such as aircraft engines, trains, offshore platforms and turbines before they are produced, and used to provide a performance analysis, predictive maintenance and live checking after the installation. Digital twins are being used in many areas, including smart transportation, and although there is an increasing amount of studies in this field, the number of studies on digital twin data modeling, which is the basic foundation stone of the digital twin, is small and insufficient. In a study that reviews the digital twin modeling in the literature, the need for a method that can represent all the information for the digital twin is highlighted. This capability can be provided by the semantic networks and this subject has been a topic of the previous studies. In this context, the studies have approached the modeling in an event-based manner and it is generally used a JavaScript Object Notation method with a semantic graphical coding for Linked Data. Apart from this, the information systems based on the different traditional filing methods have also been developed. In these developed methods, the transfer of the data that arrives from the real environment to the model is performed upon the arrival and these flows are not controlled.

For this reason, it is necessary to develop a method that minimizes or eliminates the aforementioned disadvantages of the state of the art and a system that operates according to said method.

### SUMMARY OF THE INVENTION

One of the advantages of the invention is that since the transfer of the data arriving from the real environment to the model, especially in the digital twin modeling used in the field of the intelligent transportation, is carrying out following the arrival, the problem of the inability to control said flows will be eliminated.

Another advantage of the invention is that the time intervals between the graph signals contained in the spatio-temporal graphs can be determined with a digital twin modeling method which is developed by using the semantic networks and the spatio-temporal graphs.

### DESCRIPTION OF THE FIGURES

FIG. 1: is a representative schematic view of the system according to the invention, developed for controlling the data flow and modeling data in digital twin-based intelligent transportation applications.

FIG. 2: is a representative flow diagram of the method according to the invention, developed for controlling the data flow and modeling data in digital twin-based intelligent transportation applications and modeling the data.

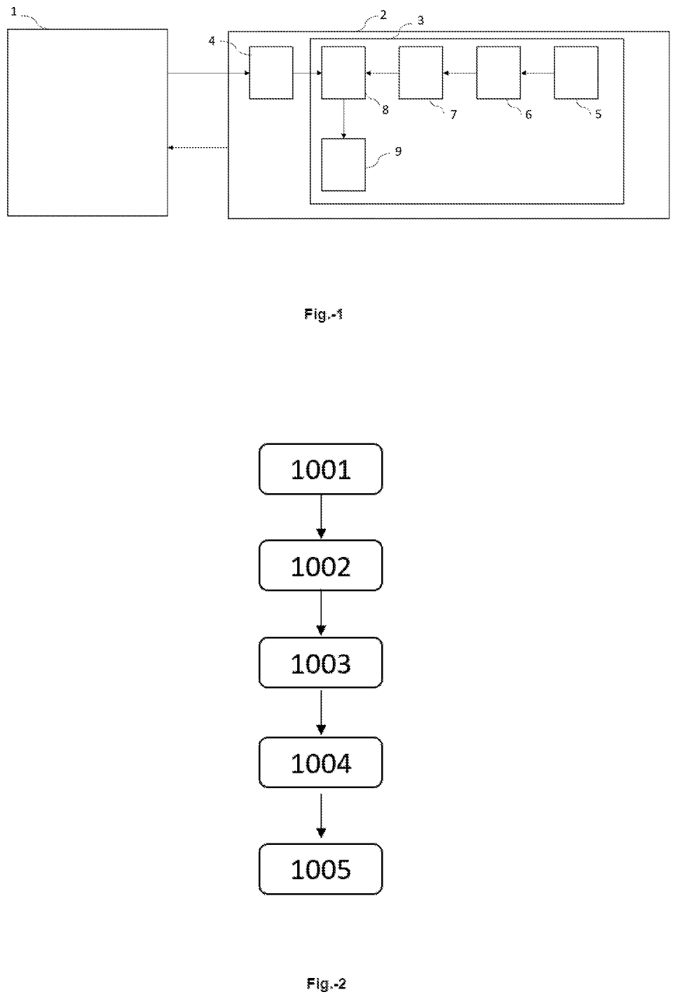

### DESCRIPTION OF THE REFERENCES IN THE FIGURES

For a better understanding of the invention, the description of the numbers in the figures is given below:
100. System
   1. Physical transportation network
   2. Digital twin layer
   3. Digital twin modeling module
   4. Adaptive twinning module
   5. Semantic network module
   6. Spatial configuration module
   7. Spatial graph module
   8. Temporal configuration module
   9. Spatio-temporal graph module
1001. Sending the data collected form the physical transportation network (1) to the digital twin layer (2)
1002. Analyzing the data reaching at the digital twin layer (2) by the adaptive twinning module (4) and calculating the adaptive twinning rate
1003. Generating a virtual copy of the physical environment by the digital twin modeling module (3) using the adaptive twinning rate
1004. Generating a spatial model of the physical environment by the spatial reconstruction module (6) using the information in the semantic network (5)
1005. Generating the spatio-temporal graph module (9) by combining the spatial graph module (7) with the data collected from the physical transportation network (1) by the temporal configuration module (8)

### DETAILED DESCRIPTION OF THE INVENTION

The example embodiments are described in more detail below with reference to the accompanying descriptions. Moreover, the embodiments can be constituted in different forms and should not be interpreted as limited to the embodiments specified here. Instead, these exemplary embodiments are provided so that this description is in all respects comprehensive and its scope is fully transmitted to those skilled in the art.

It is intended that the terminology used in this description is used only to illustrate a specific exemplary embodiment and is not intended to be limiting. As used herein, the forms “a”, “at least”, “preferably” are intended to comprise the plural forms unless its context clearly indicates otherwise. When the terms “comprises” and/other “including” are used in this specification, they do not prevent the presence or addition of the specified properties, integers, steps, processes, elements, and/or components, however one or more other properties, integers, steps, processes, elements, and/or components.

The invention relates to a system developed for controlling the two-way real-time data flow and modeling the data in the digital twin-based (DT) intelligent transportation applications and an operation method of this system. A system for controlling the data flow and modeling the data with a computer that contains at least one processor comprises:
at least one physical transportation network (1) which consists of a transportation infrastructure and includes the smart traffic lights that enable the control of the traffic and the sensors used to monitor the traffic flow and the amount of the carbon emission,
at least one digital twin layer (2) in which a real-time virtual copy of the physical environment is generated and the physical transportation network (1) is controlled
at least one digital twin modeling module (3) that models the data collected from the physical transportation network (1) so as to generate a virtual copy of the physical layer,
at least one adaptive twinning module (4) that controls the projection of the data into the digital twin model which arrives from the physical transportation network (1) to the digital twin layer module (2),
at least one semantic network module (5), which comprises information about road rules, road intersections, traffic control means and similar elements of the physical environment contained in the digital twin modeling module (3),
at least one spatial configuration module (6) that enables the representation of the spatial generation of the environment as a graph using the semantic network module (5),
at least one spatial graph module (7) in which the physical environment is represented in a spatial manner and the nodes correspond to the path intersections and the edges correspond to the path connection between them,
at least one temporal reconstruction module (8) in which a spatio-temporal graph module (8) is generated using the spatial graph module (7) with the intervals determined by the adaptive twinning module (4),
at least one three-dimensional spatio-temporal graph module (9) that models the data collected about physical environment using the spatial conditions of the physical environment.

An operation method of the system developed for controlling the two-way real-time data flow contained in the digital twin-based (DT) intelligent transportation applications according to the invention and modeling the data comprises the process steps of:
I. sending the data collected form the physical transportation network (1) to the digital twin layer (2) (1001),
II. analyzing the data reaching at the digital twin layer (2) by the adaptive twinning module (4) and calculating the adaptive twinning rate (1002),
III. generating a virtual copy of the physical environment by the digital twin modeling module (3) using the adaptive twinning rate (1003),
IV. generating a spatial model of the physical environment by the spatial reconstruction module (6) using the information in the semantic network (5) (1004),
V. generating the spatio-temporal graph module (9) by combining the spatial graph module (7) with the data collected from the physical transportation network (1) by the temporal reconstruction module (8) (1005).

In the system (100) according to the invention, the physical transportation network (1) consists of a transportation infrastructure. In said physical transportation network (1), there are the smart traffic lights that enable the control of the traffic and the sensors used to monitor the traffic flow and the amount of carbon emission. The data from said elements is sent to the digital twin layer (2). A virtual copy of the physical environment is created using this data. Said virtual copy has the capability to control the physical environment. Said copying process is called twinning and it is generated from a data-based model by the by the digital twin modeling module (3). The data arriving at the digital twin layer (2) is analyzed by the adaptive twinning module (4). Said adaptive twinning module (4) calculates the adaptive twinning rate. It is transmitted to the digital twin modeling module (3) using the mentioned ratio.

There is a digital twin model in the digital twin modeling module (3) and said model consists of a semantic network module (5) and a spatio-temporal graph module (9). The mentioned semantic networks (5) comprises information about road rules, road intersections, traffic control means and similar elements of the physical environment. Said semantic network (5) is indicated by the letter K and denoted as K=(V_{K}, E_{K}, M_{K}). Here V_{K} is the node set, edge set E_{K} is the edge set, M_{K} is the attribution set and there is an attribution vector M_{K}(v) corresponding to each node v in the node set V_{K}. Said semantic network (5) is used to indicate the static information contained in the digital twin in a self-descriptive representation.

A spatial model of the physical environment is generated by the spatial reconstruction module (6) using the information in the semantic network (5). Said spatial model is called a spatial graph module (7) and defined as S=(V_{S}, E_{S}, wₛ). In this definition, the V_{S} is the node set, E_{S} is the edge set and Wₛ is the edge weight function. The spatio-temporal graph module (9) is generated by combining the spatial graph module (7) with the data collected from the physical transportation network (1) by the temporal configuration module (8). The spatio-temporal graph module (9) has a three-dimensional structure and each node has a corresponding node vector. The temporal difference of the two successive values in the mentioned vector is obtained from the aforementioned adaptive twinning rate.

The adaptive twinning module (4) calculates the adaptive twinning rate (\hat{α}). For this purpose, the usage rate (ρᵢ) of a road intersection is calculated with the following formula by using the collected data.

$${ρ}_{i} = \frac{{flowCur}_{i} + {flowIn}_{i} - {flowOut}_{i}}{{C}_{i}} , {∀}_{i}$$

Here, flowCirᵢi indicates the vehicle/minute flowing via the road intersection, flowInᵢi represents the vehicle/minute entering the road intersection and flowOutᵢi represents the vehicle/minute leaving the road intersection. Moreover, Cᵢ is the capacity of the intersection i. Furthermore, the dynamism factor (ζᵢ) is calculated according to the following formula to measure the traffic flow variability.

$${ζ}_{i} = \frac{{flowIn}_{i} + {flowOut}_{i} + \vert {△ flowCur}_{i} \vert}{2 ( {C}_{i} + {flowIn}_{i} )} , {∀}_{i}$$

With the use of this dynamism factor (ζ) and the usage rates (ρ), an Adaptive Twinning Rate (\hat{α}) for the whole transportation network is calculated with the following formula.

$$\hat{α} \approx {argmax}_{α} {\prod }_{i = 1}^{n} {ζ}_{i} {ρ}_{i}$$

All modules contained in the system and method according to the invention carry put the operations mentioned in the invention via the processor included in the computer by means of a software.

### INDUSTRIAL APPLICABILITY OF THE INVENTION

The system of the invention and the operation method of this system will be used in all areas required for controlling of the two-way real-time data flow and modeling of the data in the digital twin-based (DT) intelligent transportation applications and are applicable to the industry.

The invention is not limited to the above exemplary embodiments and the person skilled in the art can readily present other different embodiments of the invention. These should be considered within the protection scope of the invention claimed by the claims.

1. A computer-aided system (100), which is developed for controlling the two-way real-time data flow contained in the digital twin-based intelligent transportation applications and modeling the data and which comprises at least on processor, characterized in that it comprises:
at least one physical transportation network (1) which consists of a transportation infrastructure and includes the smart traffic lights that enable the control of the traffic and the sensors used to monitor the traffic flow and the amount of the carbon emission,
at least one digital twin layer (2) in which a real-time virtual copy of the physical environment is generated and the physical transportation network (1) is controlled
at least one digital twin modeling module (3) that models the data collected from the physical transportation network (1) so as to generate a virtual copy of the physical layer,
at least one adaptive twinning module (4) that controls the projection of the data into the digital twin model which arrives from the physical transportation network (1) to the digital twin layer module (2),
at least one semantic network module (5), which comprises information about road rules, road intersections, traffic control means and similar elements of the physical environment contained in the digital twin modeling module (3),
at least one spatial configuration module (6) that enables the representation of the spatial generation of the environment as a graph using the semantic network module (5),
at least one spatial graph module (7) in which the physical environment is represented in a spatial manner and the nodes correspond to the path intersections and the edges correspond to the path connection between them,
at least one temporal reconstruction module (8) in which a spatio-temporal graph module (8) is generated using the spatial graph module (7) with the intervals determined by the adaptive twinning module (4),
at least one three-dimensional spatio-temporal graph module (9) that models the data collected about physical environment using the spatial conditions of the physical environment.

2. A system (100) according to claim 1, characterized in that it comprises
$${ρ}_{i} = \frac{{flowCur}_{i} + {flowIn}_{i} - {flowOut}_{i}}{{C}_{i}} , {∀}_{i}$$
an adaptive twinning module (4) that calculates the usage rate of a path intersection by using the data collected with the formula.

3. A system (100) according to claim 2, characterized in that it comprises
$${ζ}_{i} = \frac{{flowIn}_{i} + {flowOut}_{i} + \vert {△ flowCur}_{i} \vert}{2 ( {C}_{i} + {flowIn}_{i} )} , {∀}_{i}$$
an adaptive twinning module (4) that calculates the dynamism factor (ζᵢ) with the formula.

4. A system (100) according to claim 3, characterized in that it comprises
$$\hat{α} \approx {argmax}_{α} {\prod }_{i = 1}^{n} {ζ}_{i} {ρ}_{i}$$
an adaptive twinning module (4) that calculates the adaptive twinning rate (\hat{α}) with the formula.

5. An operation method of a system (100) according to claim 1, developed for controlling the two-way real-time data flow and modeling that data in the digital twin-based intelligent transportation applications and modeling the data, characterized in that it comprises the process steps of:
sending the data collected form the physical transportation network (1) to the digital twin layer (2) and receiving the data from the physical transportation network (1) to the digital twin layer module (2) (1001),
analyzing the data reaching at the digital twin layer (2) by the adaptive twinning module (4) and calculating the adaptive twinning rate (1002),
generating a virtual copy of the physical environment by the digital twin modeling module (3) using the adaptive twinning rate (1003),
generating a spatial model of the physical environment by the spatial reconstruction module (6) using the information in the semantic network (5) (1004),
generating the spatio-temporal graph module (9) by combining the spatial graph module (7) with the data collected from the physical transportation network (1) by the temporal reconstruction module (8) (1005).
